(19) United States
(12) Patent Application Publication
(10) Pub. No.: US 2005/0167760 A1
(43) Pub. Date: Aug. 4, 2005

(54) Semiconductor device having high-voltage and low-voltage operation regions and method of fabricating the same

(75) Inventor: Jun Takayasu, Yokkaichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/010,343

(22) Filed: Dec. 14, 2004

(30) Foreign Application Priority Data
Dec. 15, 2003 (JP) 2003-416364

(51) Int. Cl. H01L 31/062; H01L 21/336

(52) U.S. Cl. 257/391; 257/390; 438/217; 438/289; 257/500

(57) ABSTRACT

A semiconductor device includes a first region formed with a first gate insulator and operated by a first operating voltage, a second region formed with a second gate insulator made from a material having a higher dielectric constant than a material of the first insulator, the second region being operated by a second operating voltage lower than the first operating voltage, and gate electrodes including at least lowest layers which are in contact with the first and second gate insulators and are formed together with element isolation regions by a self-alignment manner respectively.

### CROSS-REFERENCE TO RELATED APPLICATION

This application claims priority to Japanese patent application No. 2003-416364, the content of which is incorporated herein by reference.

### BACKGROUND OF THE INVENTION

1. Field of the Invention

The present invention relates to a semiconductor device having a high-voltage operation region and a low-voltage operation region and a method of fabricating the semiconductor device.

2. Description of the Related Art

A semiconductor device of the above-described type includes a non-volatile memory such as flash memories. The non-volatile memory is divided into a memory cell region and a peripheral circuit region, and circuits are formed in the respective regions. In some of MOS transistors for a control circuit formed in the peripheral circuit region, data is written onto and deleted from a memory cell. Accordingly, these MOS transistors are operated at a higher voltage than circuits formed in the memory cell region.

In the aforementioned case, a transistor operated in the peripheral circuit region is required to have a higher breakdown voltage than a transistor operated in the memory cell region. A film thickness of a gate insulator has conventionally been rendered larger than a film thickness of the memory cell region to meet the requirement of high breakdown voltage of the transistor.

The following describes a process for forming a gate electrode together with an element isolation region in a self-aligning manner in the manufacture of a non-volatile memory, for example. FIG. 16A schematically illustrates part of a process of fabricating a high-voltage operation region H. FIG. 16B schematically illustrates part of a process of fabricating a low-voltage operation region L. In the high-voltage operation region H, a thick silicon oxide 2 serving as a high breakdown voltage gate insulator is formed on a silicon semiconductor substrate 1 in the high-voltage operation region H and patterned by the photolithography. An unnecessary portion is eliminated by wet etching. In the low-voltage operation region L, a thin silicon oxide 3 serving as a low breakdown voltage gate insulator is formed on the semiconductor substrate 1.

Subsequently, a first polycrystalline silicon film 4 for a gate electrode is deposited on the silicon oxide 3. An SiN film 5 for a stopper in a chemical mechanical polishing (CMP) process is then deposited on the first polycrystalline silicon film 4. A hard mask (not shown) is further deposited on the SiN film 5 and patterned by the photolithography. A part other than the gate electrode is eliminated by the photolithography such as the reactive ion etching (RIE) process. JP-A-2002-57230 discloses one example of the above-described forming process.

For example, consider a case where a difference between the high- and low-voltage operation regions H and L is increased in the aforementioned semiconductor device. In this case, when both regions H and L are flattened by a subsequent CMP process, the SiN film 5 becomes apt to be polished. See film thickness difference d in FIGS.16A and 16B. Further, in the non-volatile memories, the patterns are formed so that intervals between the patterns so as to be larger in the high-voltage operation region H which becomes a part of the peripheral circuit region than the low-voltage operation region L of the memory cell region. Accordingly, the SiN film particularly becomes apt to be polished. This results in a defect that a processing margin M is reduced in the CMP process.

### BRIEF SUMMARY OF THE INVENTION

Therefore, an object of the present invention is to provide a semiconductor device in which reduction in the processing margin M due to the level difference between the high- and low-voltage operation regions in the CMP process can be prevented from being reduced.

The present invention provides a semiconductor device comprising a first region provided with a first gate insulator and operated by a first operating voltage, a second region provided with a second gate insulator made from a material having a higher dielectric constant than a material of the first insulator, the second region being operated by a second operating voltage lower than the first operating voltage, and gate electrodes including at least lowest layers which are in contact with the first and second gate insulators and are formed together with element isolation regions by a self-alignment manner respectively.

The invention also provides a method of fabricating a semiconductor device comprising forming a first gate insulator in a first region on a semiconductor substrate, forming a second gate insulator in a second region, the second gate insulator being made from a material having a higher dielectric constant than a material of the first insulator, and forming trenches in the first and second gate insulators respectively and embedding an insulator in the trenches so that an element isolation region is defined, thereby forming at least a lowest layer of a gate electrode in a self-alignment relation with the element isolation region.

### BRIEF DESCRIPTION OF THE DRAWINGS

Other objects, features and advantages of the present invention will become clear upon reviewing the following description of the embodiment with reference to the accompanying drawings, in which:

FIGS. 1A and 1B are sectional views of high-voltage and low-voltage operation regions of a semiconductor device in accordance with an embodiment of the present invention respectively;

FIGS. 2A and 2B are sectional views of high-voltage and low-voltage operation regions of the semiconductor device in a first fabrication process respectively;

FIGS. 3A and 3B are sectional views of high-voltage and low-voltage operation regions of the semiconductor device in a second fabrication process respectively;

FIGS. 4A and 4B are sectional views of high-voltage and low-voltage operation regions of the semiconductor device in a third fabrication process respectively;

FIGS. 5A and 5B are sectional views of high-voltage and low-voltage operation regions of the semiconductor device in a fourth fabrication process respectively;

FIGS. 6A and 6B are sectional views of high-voltage and low-voltage operation regions of the semiconductor device in a fifth fabrication process respectively;

FIGS. 7A and 7B are sectional views of high-voltage and low-voltage operation regions of the semiconductor device in a sixth fabrication process respectively;

FIGS. 8A and 8B are sectional views of high-voltage and low-voltage operation regions of the semiconductor device in a seventh fabrication process respectively;

FIGS. 9A and 9B are sectional views of high-voltage and low-voltage operation regions of the semiconductor device in an eighth fabrication process respectively;

FIGS. 10A and 10B are sectional views of high-voltage and low-voltage operation regions of the semiconductor device in a ninth fabrication process respectively;

FIGS. 11A and 11B are sectional views of high-voltage and low-voltage operation regions of the semiconductor device in a tenth fabrication process respectively;

FIGS. 12A and 12B are sectional views of high-voltage and low-voltage operation regions of the semiconductor device in an eleventh fabrication process respectively;

FIGS. 13A and 13B are views similar to FIGS. 5A and 5B, showing a second embodiment of the invention respectively;

FIGS. 14A and 14B are views similar to FIGS. 12A and 12B respectively;

FIGS. 15A and 15B are views similar to FIGS. 5A and 5B, showing a prior art respectively; and

FIGS. 16A and 16B are views similar to FIGS. 12A and 12B, showing the prior art respectively.

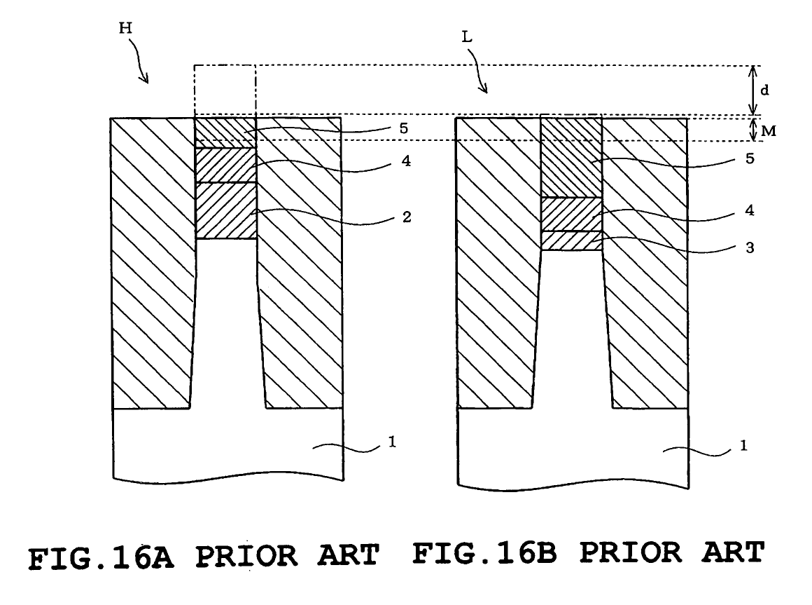

### DETAILED DESCRIPTION OF THE INVENTION

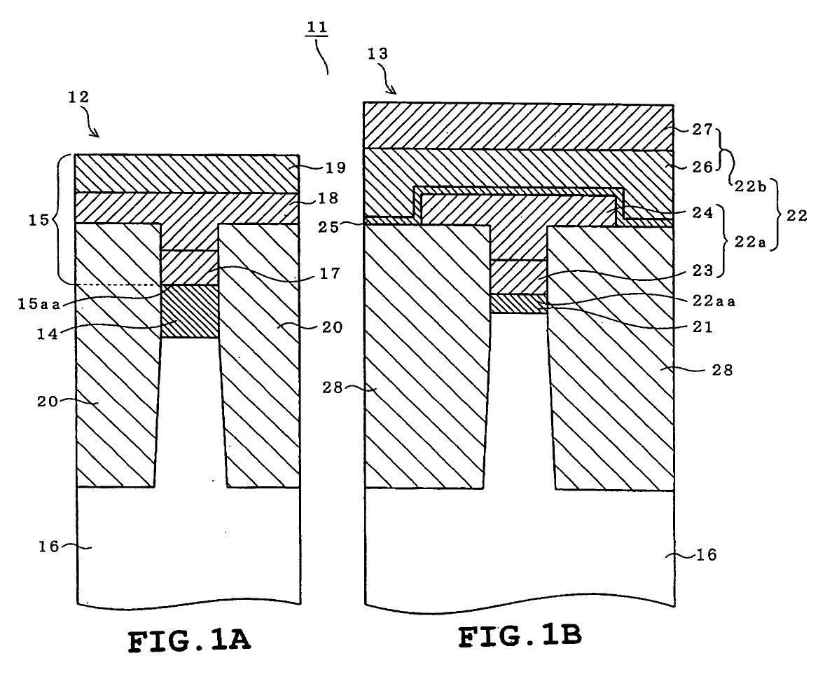

A first embodiment of the present invention will be described with reference to FIG. 1A to 12B. The invention is applied to a non-volatile memory in the embodiment. The non-volatile memory 11 has an overall structure divided into a high breakdown voltage region 12 (serving as a first region) including one part of a peripheral circuit region and a low breakdown voltage region 13 (serving as a second region) including a memory cell region and the other part of the peripheral circuit region. Accordingly, a gate structure of a MOS transistor of each region will now be described with reference to FIGS. 1A and 1B.

High Breakdown Voltage Region 12:

The following is a detailed description of the gate structure of the MOS transistor constituting a control circuit and the like in the high breakdown voltage region 12. In a region where a gate electrode 15 of the MOS transistor is to be formed, a gate insulator 14 is formed on a silicon semiconductor substrate 16 which will be abbreviated to “silicon substrate.” The gate insulator 14 is made from a silicon oxide (SiO₂ film) and has a film thickness of about 40 nm. A gate electrode 15 is formed by stacking on the gate insulator 14 a film made from a predetermined material.

Briefly describing the structure of the gate electrode 15, a first polycrystalline silicon film 17 is formed on the gate insulator 14. A second polycrystalline silicon film 18 is formed on the first polycrystalline silicon film 17. A WSi film 19 is formed on the second polycrystalline silicon film 18. Thus, the gate electrode 15 comprises the first and second polycrystalline silicon films 17 and 18 and WSi film 19. An element isolation region 20 is defined in order that the gate electrode 15 of each MOS transistor may electrically be isolated from the gate electrode 15 of the adjacent MOS transistor. A diffusion layer (not shown) is formed with the gate electrode 15 serving as a mask. A cell of MOS transistor is formed with the diffusion layer serving as drain and source. In the drawings, the thickness obtained after gate oxidation is shown with exaggeration.

Low Breakdown Voltage Region 13:

The following describes the structure of a gate insulator 21 and a gate electrode 22 of a transistor having the MOS structure in the low breakdown voltage region 13. Some of the transistors with the MOS structure formed in the high breakdown voltage region 12 are directed to execution of a process of writing data onto and/or deleting data from a memory cell. Further, since transistors formed in the low breakdown voltage region 13 need to have a quick response characteristic, they need to be formed so as to have a lower breakdown voltage than the transistors of the high breakdown voltage region 12.

A second gate insulator 21 is formed in a region different from the region where the first gate insulator 14 is formed on the semiconductor substrate 16. The second gate insulator 21 is made from a material containing Al₂O₃ (aluminum oxide) which is a material having a high dielectric constant. The second gate insulator 21 is formed to have a film thickness of about 12.5 nm. The material containing Al₂O₃ (aluminum oxide) has a dielectric constant of about 10 and thus has a higher dielectric constant than a dielectric constant of silicon oxide (SiO₂ film), which is about 4.

A semiconductor device retains the same performance if the density of electron (negative charge carrier) induced during formation of an inversion layer or density of positive hole (positive charge carrier) does not change. Accordingly, when the gate insulator 21 is made from the material containing Al₂O₃ (high-k material), the gate insulator 21 can physically be rendered thicker as compared with a case where it is made from silicon oxide (SiO₂) More specifically, the gate insulator 21 made from the material containing Al₂O₃and having a film thickness of 12.5 nm has the same function as a gate insulator made from silicon oxide and having a film thickness of 5 nm.

The dielectric constant can be improved when silicon oxide is employed as a material for the gate insulator 21 and nitrided. However, even if silicon oxide is nitrided, the dielectric constant can be increased to a range from 5 to 6 at the most, whereupon a sufficient advantage cannot be achieved from the difference in the film thicknesses. In the embodiment, however, the second gate insulator 21 is made from the material containing Al₂O₃ (aluminum oxide). Consequently, a sufficient advantage can be achieved from the film thickness difference.

A first polycrystalline silicon film 23 is formed on the gate insulator 21. A second polycrystalline silicon film 24 is formed on the first polycrystalline silicon film 23. The first and second polycrystalline silicon films 23 and 24 serve as an electron (charge) accumulation layer of a floating gate electrode 22. Further, an ONO (oxide-nitride-oxide) film 25 serving as an insulating film is formed on the second polycrystalline silicon film 24. The ONO film 25 is formed to have a predetermined film thickness to cover an upper surface and opposite sides of the second polycrystalline silicon film 24. Further, the ONO film 25 is formed to prevent the electric charge stored in the silicon films 23 and 24 from leaking outward together with the gate insulator 21 and element isolation region 28 unless a predetermined voltage is applied to the gate electrode 22.

A third polycrystalline silicon film 26 is formed on the ONO film 25. A tungsten-silicide (WSi) film 27 is formed on the third polycrystalline silicon film 26. The third polycrystalline silicon film 26 and WSi film 27 serve as a conductor of a control gate of the non-volatile memory. Thus, the gate electrode 22 is formed by the first and second polycrystalline silicon films 23 and 24, ONO film 25, third polycrystalline silicon film 26 and WSi film 27. Further, the element isolation region 28 is formed to isolate the MOS transistor elements (including gate electrodes 22) from the other circuit elements. Although drain and source regions are formed in the low breakdown voltage region 13, too, the description of them will be eliminated.

Fabricating Method:

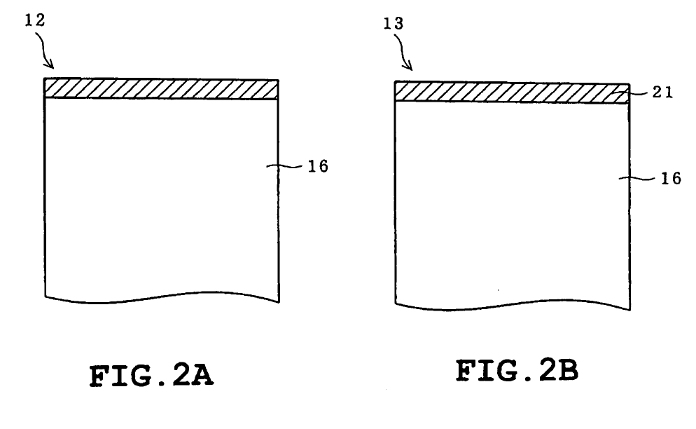

The method of fabricating the non-volatile memory 11 will now be described with reference to FIGS. 2A to 12B. The fabricating method is described while the high and low breakdown voltage regions 12 and 13 are compared with each other.

As shown in FIGS. 2A and 2B, the gate insulator 21 made from Al₂O₃ is deposited on each of the high and low breakdown voltage regions 12 and 13 so that the gate insulator 21 has a film thickness of 12.5 nm. The Al₂O₃ film has a dielectric constant of about 10 and serves as the gate insulator 21 in the low breakdown voltage region 13.

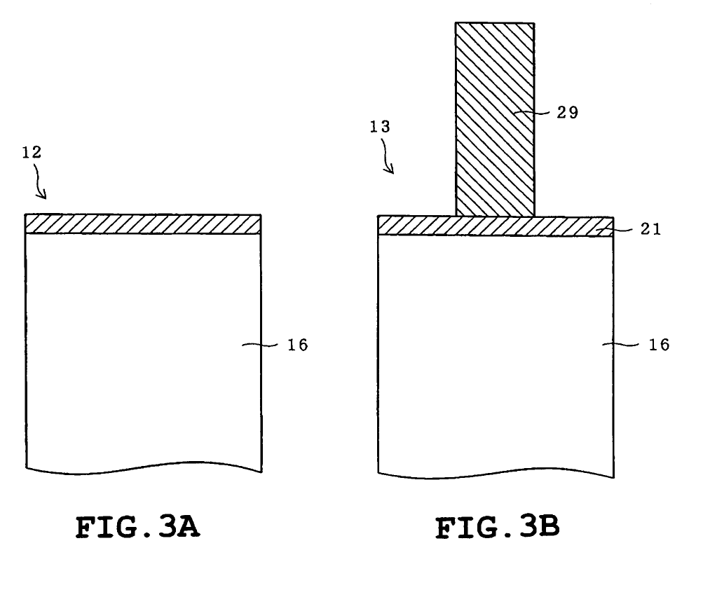

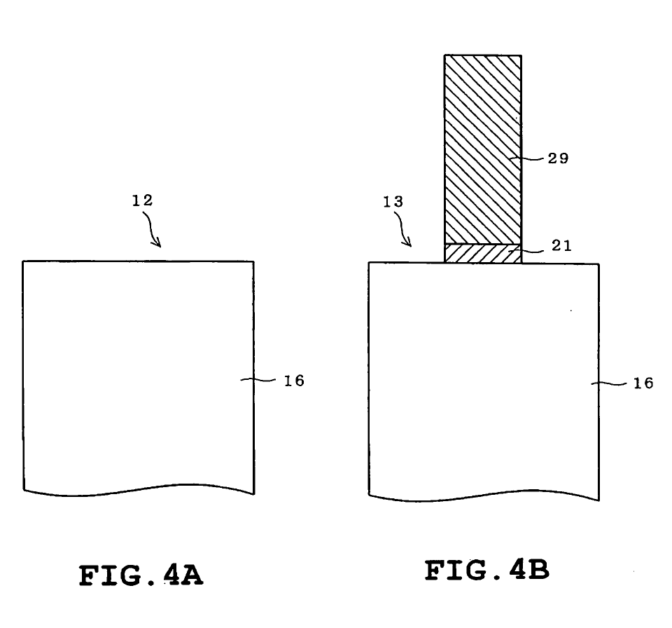

As shown in FIGS. 3A and 3B, a resist 29 is applied to the gate insulator 21 and then patterned. Subsequently, as shown in FIGS. 4A and 4B, a part of the Al₂O₃ film other than required part is eliminated by a reactive ion etching (RIE) process.

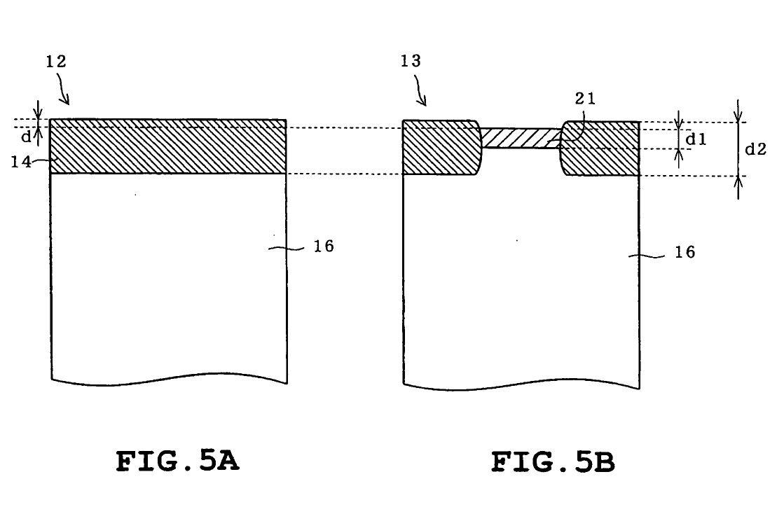

As shown in FIGS. 5A and 5B, after removal of the resist 29, a surface of the silicon substrate 16 is thermally oxidated, whereby the first gate insulator 14 is formed. The first gate insulator 14 serves as a gate insulator of the transistor in the high breakdown voltage region 12. The first gate insulator 14 is formed to have a larger film thickness than the second gate insulator 21 formed in the low breakdown voltage region 13 and having a film thickness of about 12.5 nm. This silicon oxide is formed to have a film thickness of about 40 nm (20 nm in each of the vertically opposite directions with respect to the surface of the silicon substrate 16.

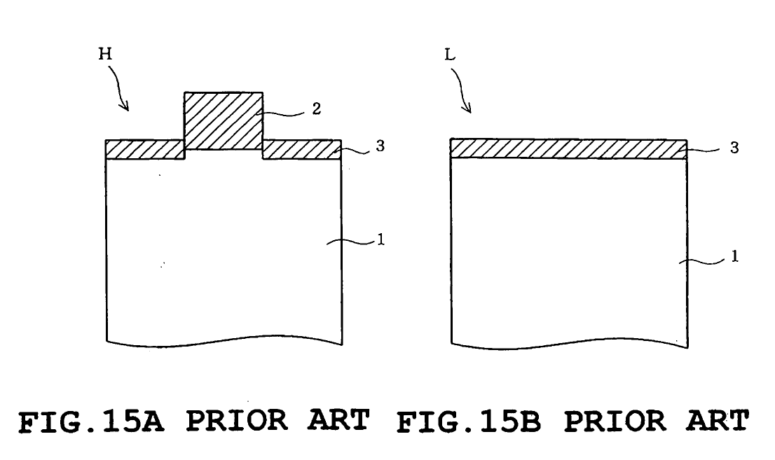

For example, when the second gate insulator 21 has a film thickness d1 of 12.5 nm and the first gate insulator 14 is formed to have a film thickness of 20 nm in each of the vertically opposite directions with respect to the surface of the silicon substrate 16 or the film thickness d2 of 40 nm, a physical level difference d between the surfaces of the second and first gate insulators 21 and 14 is 7.5 nm. The level difference d is smaller than that in a case where each of the gate insulators 14 and 21 is made from the silicon oxide (see FIGS. 15A and 15B).

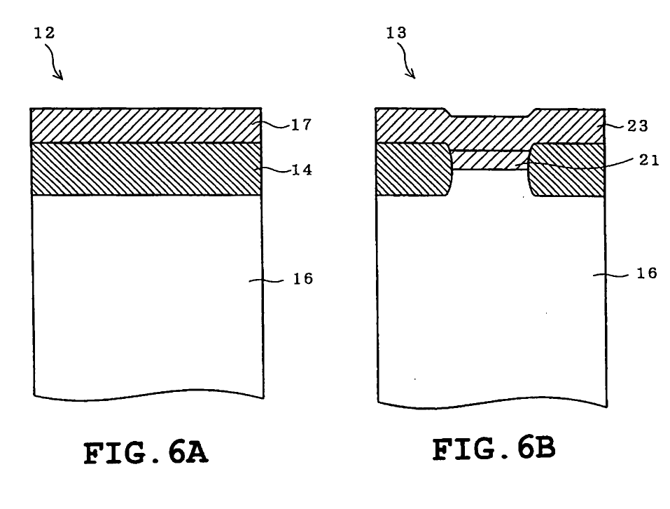

Subsequently, as shown in FIGS. 6A and 6B, the first polycrystalline silicon films 17 and 23 are simultaneously formed in the high and low breakdown voltage regions 12 and 13 respectively. The first polycrystalline silicon films 17 and 23 are designated by different reference numerals since they have different functions in the high and low breakdown voltage regions 12 and 13. However, the first polycrystalline silicon films 17 and 23 are simultaneously formed on the gate insulators 14 and 21 so as to have the same film thickness.

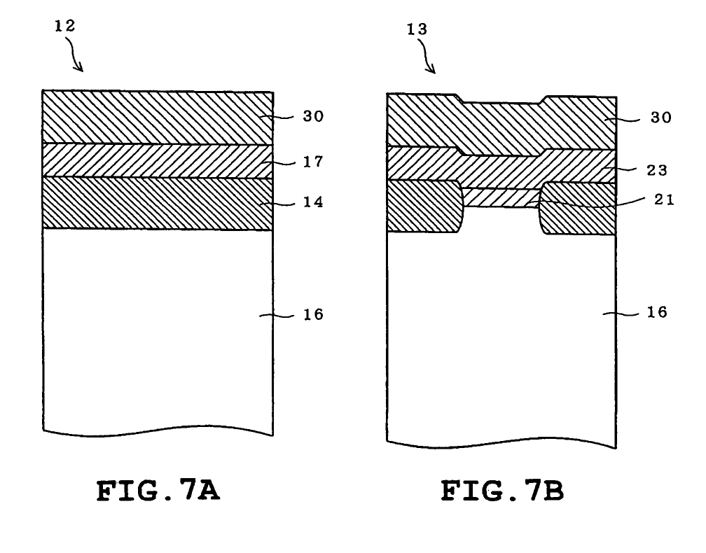

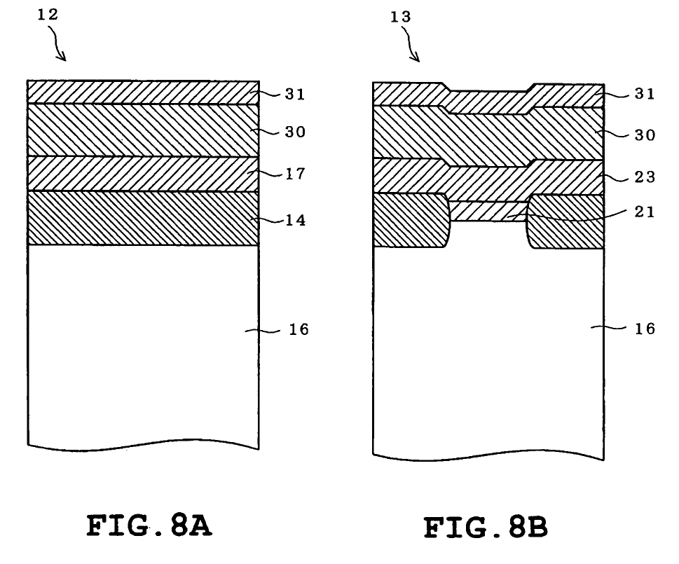

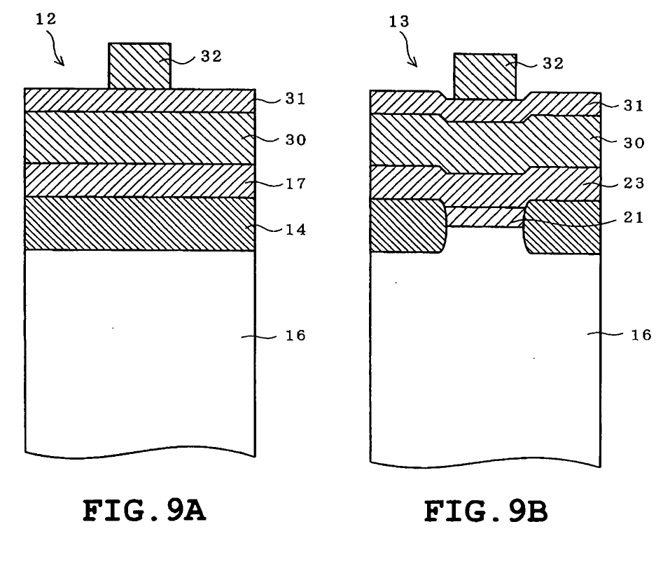

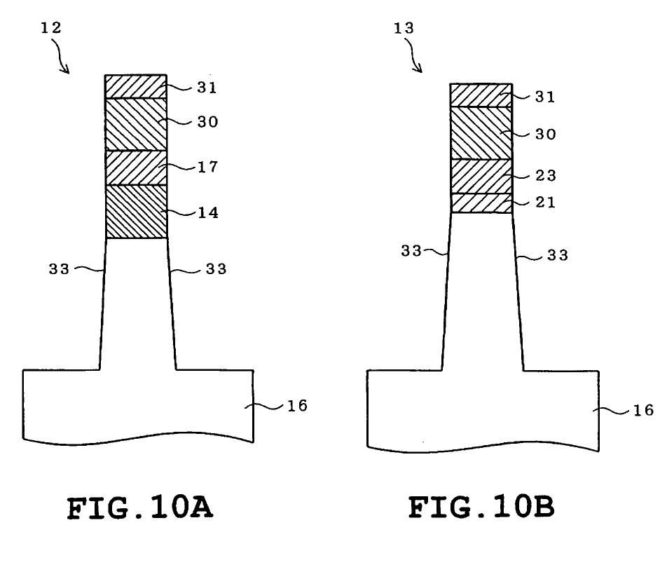

Subsequently, as shown in FIGS. 7A and 7B, an SiN film 30 is stacked in the high and low breakdown voltage regions 12 and 13. The SiN film 30 serves as a stopper in a CMP process. After formation of the SiN film 30, as shown in FIGS. 8A and 8B, a hard mask 31 made by TEOS is deposited on the SiN film 30. Subsequently, as shown in FIGS. 9A and 9B, the hard mask 31 is coated with a resist 32 and then patterned by the photolithography. Subsequently, as shown in FIGS. 10A and 10B, an etching process by way of RIE process is carried out so that a trench 33 for forming the element isolation region. A thermal oxidation process is carried out so that the surface of the trench 33 is protected, although the process is not shown.

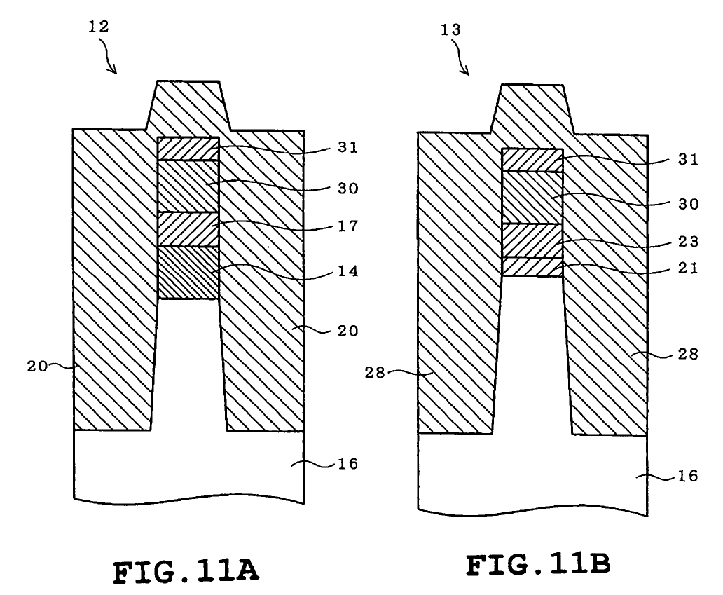

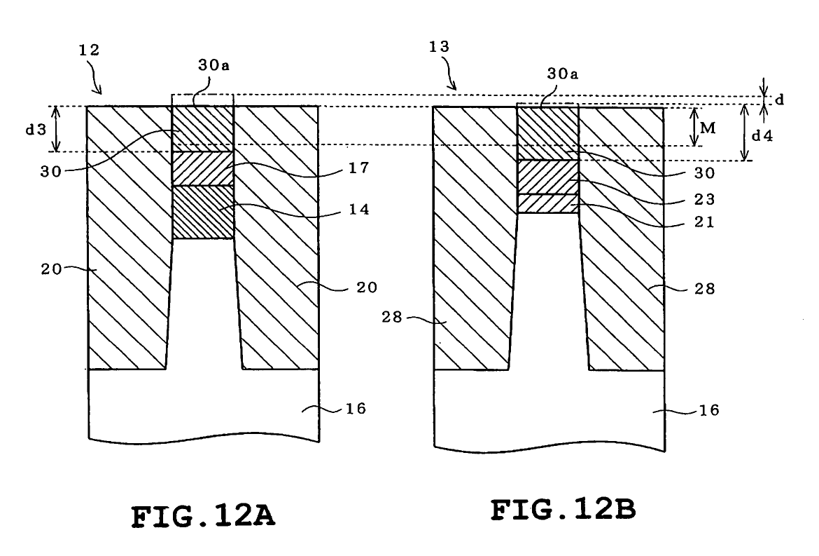

Subsequently, as shown in FIGS. 11A and 11B, the insulating films 20 and 28 are buried in the trenches 33 formed in the high and low breakdown voltage regions 12 and 13 respectively. Further, as shown in FIGS. 12A and 12B, a CMP process is carried out for the high and low breakdown voltage regions 12 and 13 to flatten the surfaces of the embedded insulating films 20 and 28 so that an element isolation region is defined. In this case, since the high and low breakdown voltage regions 12 and 13 are simultaneously processed by the CMP process, an upper surface of the insulating film 28 of the low breakdown voltage region 13 is formed to be located at the same level as an upper surface of the SiN film 30, and a surface of the insulating film 20 processed by the CMP process in the high breakdown voltage region 12 is formed to be located at the same level as an upper surface 30a of the SiN film 30.

A level difference between the layers of the low and high breakdown voltage regions 13 and 12 after the CMP process is obtained in the following manner. The first polycrystalline silicon films 17 and 23 and SiN film 30 are stacked on the gate insulators 14 and 21 of the high and low breakdown voltage regions 12 and 13 so as to have thicknesses equal to each other, respectively. Accordingly, at a stage prior to the CMP process (see two-dot chain lines in FIGS. 12A and 12B), too, the level difference d between the high and low breakdown voltage regions 12 and 13 on the upper surface of the SiN film 30 substantially corresponds with the level difference between the gate insulators 14 and 21.

More specifically, the level difference on the upper surface at the stage prior to the CMP process is about 7.5 nm. The CMP process is carried out at this stage so that the insulating films 20 and 28 are polished until the upper surfaces are nearly reached, whereupon the upper surfaces 30a of the SiN films 30 of the regions 12 and 13 are exposed. In this case, the upper surfaces 30a are formed so as to be coplanar.

In this case, as shown in FIGS. 12A and 12B, the film thickness d3 of the SiN film 30 in the high breakdown voltage region 12 is thinner than the film thickness d4 of the SiN film 30 in the low breakdown voltage region 13. The level difference between the thicknesses d3 and d4 substantially corresponds with the level difference d (=about 7.5 nm) and is exceedingly smaller as compared with that in the conventional semiconductor devices. Accordingly, a processing margin M can be rendered larger as compared with that of the conventional semiconductor devices in the CMP process. Consequently, a sufficient process capability can be afforded, and the number of occurrences of failure can be reduced as small as possible even when a severe specification is required.

Subsequent processes include an annealing process of destressing the insulating films 20 and 28 embedded in the element isolation region and a wet etching process for selective elimination of the SiN film 30. As shown in FIGS. 1A and 1B, the second polycrystalline silicon film 24 is stacked on the first polycrystalline silicon film 23 in the low breakdown voltage region 13 and at the same time, the second polycrystalline silicon film 1B is also stacked on the first polycrystalline silicon film 23 in the high breakdown voltage region 12.

Subsequently, an etching process is carried out in the low breakdown voltage region 13 so that the second polycrystalline silicon film 24 is separated. An ONO film 25 is formed on an upper surface of the separated second polycrystalline silicon film 24 so that the floating gate electrode 22a is formed. Thereafter, a third polycrystalline silicon film 26 is formed, and a tungsten silicide (WSi) film 27 is formed on the third silicon film 26, whereby a control gate electrode 22b is formed.

On the other hand, in the high breakdown voltage region 12, too, the second polycrystalline silicon film 18 is stacked and subsequently, the ONO film 25 and the third polycrystalline silicon film 26 are in turn stacked simultaneously with the low breakdown voltage region 13. Thereafter, the films 25 and 26 are removed by the etching process. Subsequently, the WSi film 19 is formed on the second polycrystalline silicon film 18 concurrently with the stacking of the WSi film 27 in the low breakdown voltage region 13.

Subsequently, in the low breakdown voltage region 13, the first and second polycrystalline silicon films 23 and 24, ONO film 25, third polycrystalline silicon film 26 and WSi film 27 are processed so that the gate electrode 22 having a predetermined shape is formed. More specifically, in each of the high and low breakdown voltage regions 12 and 13, the gate insulators 14 and 21 are formed together with the element isolation region (shallow trench isolation, STI) in the self-alignment manner. Since the embodiment is characterized by the method of fabricating a gate electrode structure, the other part of the method of fabricating the semiconductor device will be summarized as follows: in the high and low breakdown voltage regions 12 and 13, both regions 12 and 13 are doped with impurities, and a thermal diffusion process is carried out so that drain and source diffusion layers are formed in the transistor. Subsequently, an interlayer insulator is deposited and a contact hole is made in the contact region so that the diffusion layer located under the interlayer insulator is exposed. A metal such as tungsten is embedded in the hole, so that a contact plug is formed. Subsequently, a wiring layer is formed on the interlayer insulator, and the wiring layer is connected to the contact plug. Thus, the non-volatile semiconductor storage device 11 is formed through the foregoing processes.

In the method of fabricating the device 11, the upper surface of the silicon substrate 16 is oxidized so that a silicon oxide is formed, whereby the gate insulator 14 is formed (see FIGS. 5A and 5B). Ideally, it is desirable that at the same time, the upper surface (the lowest layer 22aa of the gate electrode 22; and see FIG. 1B) of the gate insulator 21 of the transistor in the low breakdown voltage region 13 should completely be coplanar with the upper surface of the gate insulator 14 of the transistor (the lowest layer 15aa of the gate electrode 15; and see FIG. 1A) in the high breakdown voltage region 12. However, the gate structures 15 of the transistors in the high and low breakdown voltage regions 12 and 13 need to meet required breakdown voltage characteristics. Actually, the gate insulators 21 and 14 are formed in the low and high breakdown voltage regions 13 and 12 so as to have predetermined thicknesses according to the dielectric constants respectively, so that the upper surfaces of the gate insulators 21 and 14 are formed to be substantially coplanar as much as possible.

In the foregoing embodiment, the metal oxide (Al₂O₃) containing Al is employed as the material for the gate insulator 21 in the low breakdown voltage region 13, and SiO₂ is employed as the material for the gate insulator 14 in the high breakdown voltage region 12. The gate insulators 14 and 21 are formed so as to have the difference of 7.5 nm between the upper surfaces of them while the film thickness of the gate insulator 14 is increased as compared with the film thickness of the gate insulator 21. Further, the breakdown voltage characteristics of the gate insulators 14 and 21 are rendered applicable to the high and low withstand pressure regions 12 and 13 respectively. Thereafter, the first polycrystalline silicon films 17 and 23 and the SiN films 30 for the CMP stopper are stacked so that the same film thickness is obtained in the high and low breakdown voltage regions 12 and 13 and subsequently, the CMP process is carried out for the stacked films 17, 23 and 30. Consequently, the level difference between the high and low breakdown voltage regions 12 and 13 before execution of the CMP process can be reduced as compared with the conventional structure, and accordingly, the processing margin in the CMP process can be increased.

### Second Embodiment

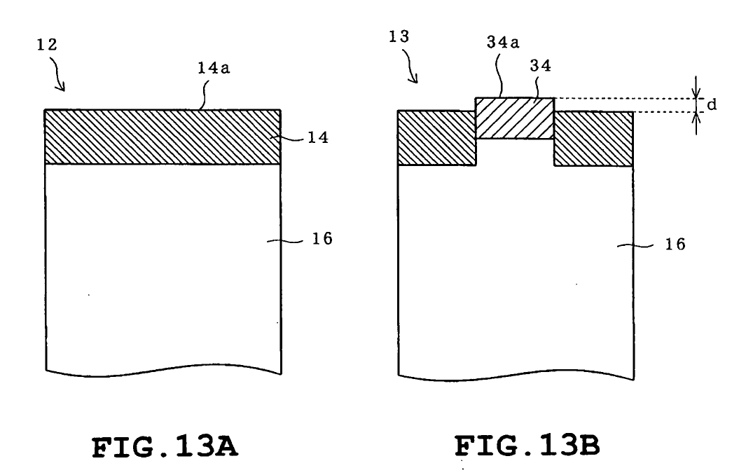

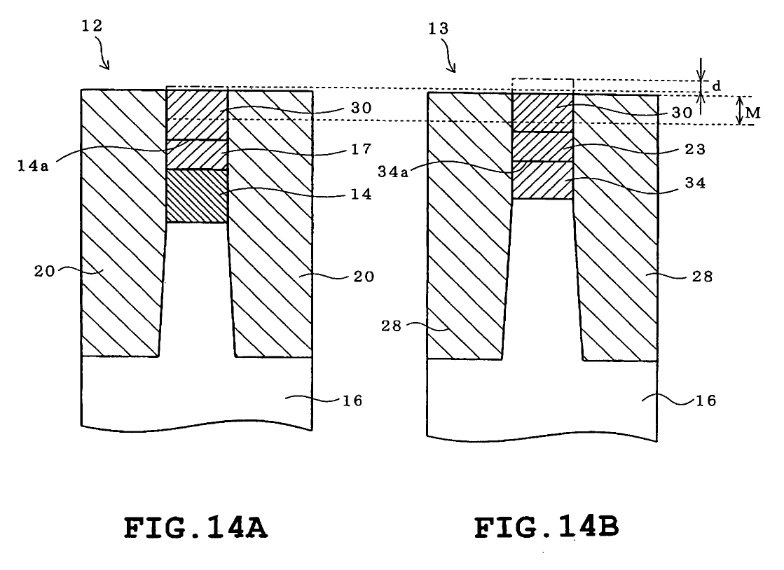

FIGS. 13A to 14B illustrate a second embodiment of the invention. The second embodiment differs from the first one in that the gate insulator is made from ZrO₂, instead of Al₂O₃. The identical or similar parts in the second embodiment are labeled by the same reference symbols as those in the first embodiment and description of these parts will be eliminated. Only the difference of the second embodiment from the first embodiment will now be described.

ZrO₂ has a dielectric constant of about 24 and accordingly has a higher dielectric constant than Al₂O₃. A gate insulator 34 made from ZrO₂ is formed on the silicon substrate 16, instead of the gate insulator 21 described in the first embodiment. As in the first embodiment, when the gate insulator 34 is made from ZrO₂, a physical increase in the film thickness can be achieved as compared with a case where a film having the same function as the film 34 is made from the silicon oxide.

More specifically, a gate insulator made from ZrO₂ and having a film thickness of 30 nm is functionally identical with a gate insulator made from SiO₂ and having a film thickness of 5 nm. Accordingly, in order that a film may be formed which has the same function as that of the film described with reference to FIGS. 15A and 15B, it is desirable that the gate insulator 34 has a thickness of 30 nm. In this case, the gate insulator is formed on the surface of the silicon substrate 16 so as to have a film thickness of 40 nm (20 nm in each of the vertically opposite directions with respect to the surface of the silicon substrate 16, the upper surface of the gate insulator 34 is located higher than the upper surface 14a of the first gate insulator 14 but the difference d becomes about 10 nm, which value is smaller than those in the conventional semiconductors. Consequently, the second embodiment can achieve the same effect as the first embodiment. The other constituent is substantially the same as that in the first embodiment.

Further, when the non-volatile memory described in the first embodiment is fabricated, for example, the gate insulator 34 made from ZrO₂ is included in the low breakdown voltage region 13. Since this gate insulator 34 is located in a dense portion which is crowded with memory cells, a portion where the SiN film 30 is exposed has a higher share in the flattening process by the CMP process.

Accordingly, a polishing speed is restrained and consequently offset such that the difference in an amount of remaining film in the IC chip can be limited and a pattern dependency can be reduced in the CMP process.

In the second embodiment, the gate insulator 14 of the high breakdown voltage region 12 is made from SiO₂ so as to have a thickness of 40 nm, and the gate insulator 34 of the low breakdown voltage region 13 is made from ZrO₂ so as to have a thickness of 30 nm. The gate insulator 14 in the high breakdown voltage region 12 is formed so that the upper surface thereof is lower by 10 nm than the upper surface 34a of the gate insulator 34 in the low breakdown voltage region 13. Thereafter, the first polycrystalline silicon films 17 and 23 and SiN film 30 are stacked in the high and low breakdown voltage regions12 and 13 so that the same film thickness. Consequently, only a difference of 10 nm is produced such that the processing margin M is increased. Further, the same effect can be achieved from the second embodiment as the first embodiment. Additionally, pattern dependency can be reduced in the CMP process.

Modified Forms:

The invention should not be limited to the foregoing embodiments but may be modified or expanded as follows. The gate insulator 21 or 34 is made from Al₂O₃ or ZrO₂ in each of the foregoing embodiments. The material for the gate insulator 21 or 34 should not be limited to this. For example, the gate insulator 21 or 34 may be made from a high dielectric constant material comprising a metal oxide or metal oxide containing aluminum (Al), zirconium (Zr), lanthanum (La), praseodymium (Pr) or tantalum (Ta) or metal nitride, for example, Hf (hafnium) —Si—O—N, Hf—Si, HfO₂ or the like. Any fabricating method may be employed only if at least the lowest layers 15aa and 22aa of the gate electrodes 15 and 22 are formed in the self-alignment manner together with the element isolation region.

The gate insulator 21 of the transistor in the low breakdown voltage region 13 is made from Al₂O₃ or ZrO₂ in each of the foregoing embodiments. However, the material for the gate insulator 21 should not be limited to Al₂O₃ or ZrO₂. Both gate insulators 14 and 21 of the high and low breakdown voltage regions 12 and 13 may be used for the conventional silicon oxide. In this case, both gate insulators may be made from materials having different dielectric constants.

Further, the invention may be applied to any semiconductor device having high and low breakdown voltage regions other than the non-volatile memory.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

1. A semiconductor device comprising:
a first region provided with a first gate insulator and operated by a first operating voltage;
a second region provided with a second gate insulator made from a material having a higher dielectric constant than a material of the first insulator, the second region being operated by a second operating voltage lower than the first operating voltage; and
gate electrodes including at least lowest layers which are in contact with the first and second gate insulators and are formed together with element isolation regions by a self-alignment manner respectively.

2. The semiconductor device according to claim 1, wherein the first and second gate insulators have upper surfaces respectively and are formed so that the upper surface of the second gate insulator is located higher than the upper surface of the first gate insulator.

3. The semiconductor device according to claim 1, wherein at least one of the first and second gate insulators is made from a material with a predetermined high dielectric constant, said material comprising a metal oxide containing Hf or a metal nitride.

4. The semiconductor device according to claim 2, wherein at least one of the first and second gate insulators is made from a material with a predetermined high dielectric constant, said material comprising a metal oxide containing Hf or a metal nitride.

5. The semiconductor device according to claim 1, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

6. The semiconductor device according to claim 2, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

7. The semiconductor device according to claim 3, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

8. A method of fabricating a semiconductor device comprising:
forming a first gate insulator in a first region on a semiconductor substrate;
forming a second gate insulator in a second region, the second gate insulator being made from a material having a higher dielectric constant than a material of the first insulator; and
forming trenches in the first and second gate insulators respectively and embedding an insulator in the trenches so that an element isolation region is defined, thereby forming at least a lowest layer of a gate electrode in a self-alignment relation with the element isolation region.

9. The method according to claim 8, wherein the first and second gate insulators have upper surfaces respectively and are formed so that the upper surface of the second gate insulator is located higher than the upper surface of the first gate insulator.

10. The method according to claim 8, wherein at least one of the first and second gate insulators is made from a material with a predetermined high dielectric constant, said material comprising a metal oxide containing Hf or a metal nitride.

11. The method according to claim 9, wherein at least one of the first and second gate insulators is made from a material with a predetermined high dielectric constant, said material comprising a metal oxide containing Hf or a metal nitride.

12. The method according to claim 8, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

13. The method according to claim 9, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

14. The method according to claim 10, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.

15. The method according to claim 11, wherein at least one of the first and second gate insulators is made from a material with a predetermined high dielectric constant, said material comprising a metal oxide containing Al, Zr, La, Pr or Ta, a nitride of Al, Zr, La, Pr or Ta or a silicate.
